(19) United States
(12) Patent Application Publication
(10) Pub. No.: US 2008/0070331 A1
(43) Pub. Date: Mar. 20, 2008

(54) METHOD FOR MANUFACTURING A STRONGLY REFRACTIVE MICROLENS FOR A LIGHT EMITTING DIODE WITH CONDENSATION SILICONE

(75) Inventor: Chuan Ke, Taichung City (TW)

Correspondence Address: PATENTTM.US, P. O. BOX 82788, PORTLAND, OR, 97282-0788, US

(73) Assignee: Chuan KE, Hsi-Tien CHANG, Pu SHEN

(21) Appl. No.: 11/532,830

(22) Filed: Sep. 18, 2006

(51) Int. Cl. H01L 21/00

(52) U.S. Cl. 438/22

(57) ABSTRACT

A method for manufacturing a strongly refractive microlens for an LED with condensation silicone has steps of: forming a mixture of composite nanoparticles and PMMA microspheres, forming a mixture of condensation silicone and photonic crystals and injecting the condensation silicone and photonic crystals onto an LED to form a strongly refractive microlens on an LED. A photonic crystal structure is an integral part of an encapsulating layer of the LED, and the luminous efficiency of the LED is improved. In addition, the condensation silicone serves as material for an encapsulating layer for the LED and is helpful to reduce the LED manufacturing cost.

### BACKGROUND OF THE INVENTION

1. Field of Invention

The present invention relates to a method for manufacturing a strongly-refractive microlens for a light emitting diode (LED), and more particularly to a method for forming a photonic crystal structure in the encapsulating layer of an LED, which improves the luminous efficiency of the LED.

2. Description of the Related Art

Common white LEDs use a blue LED chip covered by YAG fluorescence. The blue LED chip emits blue light, part of which is efficiently converted to yellow light by the YAG fluorescence. The resulting mix of blue and yellow light gives the appearance of white.

White LEDs have extremely long life spans and a very small volume. The energy required by white LEDs is also quite low. However, white LEDs still have an important problem to be overcome. The luminous efficiency of white LEDs is lower than a fluorescent lamp. Internally generated light in white LEDs is lost as a result of total internal reflection associated with the high refractive indices of the substrates.

Therefore, when light emitted by an LED chip passes through an encapsulating layer of the white LED, part of the light is totally reflected and only a small amount of the light goes outside the white LED, which lowers the luminous efficiency of the white LED. One way to overcome this problem is to use a photonic crystal structure in the encapsulating layer of white LEDs, which can change the characteristics of the light passing through the encapsulating layer and decrease the total reflection.

Photonic band gaps were first predicted in 1987 by E. Yablonovitch and S. John. They suggested that the propagation of electromagnetic waves in a periodic arrangement of refractive index variation structure called a photonic crystal have a phenomenon of a band structure characterized by a photonic band gap. Electromagnetic waves can only propagate in a range of wavelengths called a photonic band gap. Since the photonic band gap phenomenon is based on diffraction, the periodicity of the photonic crystal structure has to be in the same length-scale as the wavelength of the electromagnetic waves. Therefore, using a photonic crystal structure in the encapsulating layer of LEDs will allow more light to pass through the encapsulating layer.

Furthermore, silicone material used in the encapsulating layers of LEDs is usually liquid addition silicone that has advantages of heat-resistant and high peel strength. However, addition silicone is rather expensive, which increases the cost of manufacturing LEDs.

To overcome the shortcomings, the present invention provides a method for manufacturing a strongly refractive microlens for an LED with condensation silicone to mitigate or obviate the aforementioned problems.

### SUMMARY OF THE INVENTION

The primary objective of the present invention is to provide a method for manufacturing a strongly refractive microlens for an LED with condensation silicone, which uses a photonic crystal structure in an encapsulating layer of an LED and improves the luminous efficiency of the LED.

Another objective of the present invention is to provide a method for manufacturing a strongly refractive microlens for LED with condensation silicone that is the LED encapsulating layer material and reduces the LED manufacturing cost.

A method for manufacturing a strongly refractive microlens for an LED with condensation silicone in accordance with the present invention comprises steps of: forming a mixture of composite nanoparticles and PMMA microspheres, forming a mixture of condensation silicon and photonic crystals and injecting the condensation silicone and photonic crystals onto an LED to form a strongly refractive microlens.

Other objectives, advantages and novel features of the invention will become more apparent from the following detailed description when taken in conjunction with the accompanying drawings.

### BRIEF DESCRIPTION OF THE DRAWINGS

FIG. 1 is a flow diagram of a method for manufacturing a strongly refractive microlens for a light emitting diode;

FIG. 2 is a schematic diagram of the composite nanoparticles grafted on the PMMA microsphere;

FIG. 3 is a schematic diagram of the composite nanoparticles grafted on the PMMA microsphere to form a photonic crystal structure;

FIG. 4 is a schematic diagram of forming a convex microlens on an LED chip;

FIG. 5 is a schematic diagram of forming a concave microlens on an LED chip;

FIG. 6 is a schematic diagram of a series of concave microlens on LED chips arranged in a line; and

FIG. 7 is a schematic diagram of a microlens on an LED product.

### DETAILED DESCRIPTION OF THE INVENTION

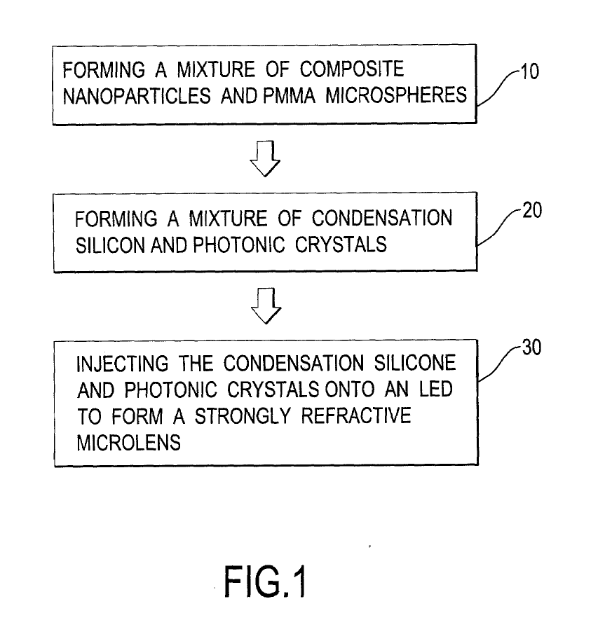

With reference to FIG. 1, a method for manufacturing a strongly refractive microlens for an LED with condensation silicone in accordance with the present invention comprises steps of: (10) forming a mixture of composite nanoparticles (61) and PMMA microspheres (63), (20) forming a mixture of condensation silicon (71) and photonic crystals (60) and (30) injecting the condensation silicone (71) and photonic crystals (60) onto an LED to form a strongly refractive microlens.

In the forming a mixture of composite nanoparticles and PMMA microspheres step (10), composite nanoparticles (61), organic metal coupling agent (62), PMMA microspheres (63) and organic solvent are mixed. The composite nanoparticles (61) are mixed with and encapsulated by the organic metal coupling agent (62) to form a paste. The paste is dripped into and mixed with a mixed liquid of the PMMA microspheres (63) and the organic solvent to form a mixture of the composite nanoparticles (61) and the PMMA microspheres (63).

The composite nanoparticles (61) have a diameter in a range of 5 nm-1000 nm and may be a 4 to 1 mixture of titanium dioxide (TiO2) nanoparticles and silica (SiO2) nanoparticles. The titanium dioxide nanoparticles are transparent and photocatalytic and absorb ultraviolet radiation.

The organic metal coupling agent (62) can be titanate, aluminate or stannate coupling agent. Furthermore, light has chromaticity that can be adjusted by changing the organic functional groups of the organic metal coupling agent (62).

The PMMA microspheres (63) scatter light, can increase uniformity of the light, form a steric light source and have a diameter in a range of 0.1 μm-20 μm and a weight ratio to the composite nanoparticles (61) of 80:20 through 99:1.

The organic solvent may be a mixture of ethanol and methylbenzene.

In the forming a mixture of condensation silicon (71) and photonic crystals (60) step (20), the mixture of the composite nanoparticles (61) and the PMMA microspheres (63) is added to and mixed with condensation silicone (71), the organic solvent and water are removed from the mixture, and the composite nanoparticles are grafted uniformly onto the PMMA microspheres to form photonic crystals.

The composite nanoparticles (61) and the PMMA microspheres (63) mixture is added to and mixed with condensation silicone (71) at about 120° C. and near a vacuum to remove impurities including the organic solvent and water from the mixture. The condensation silicone (71) is cheaper than addition silicone, waterproofs and radiates heat.

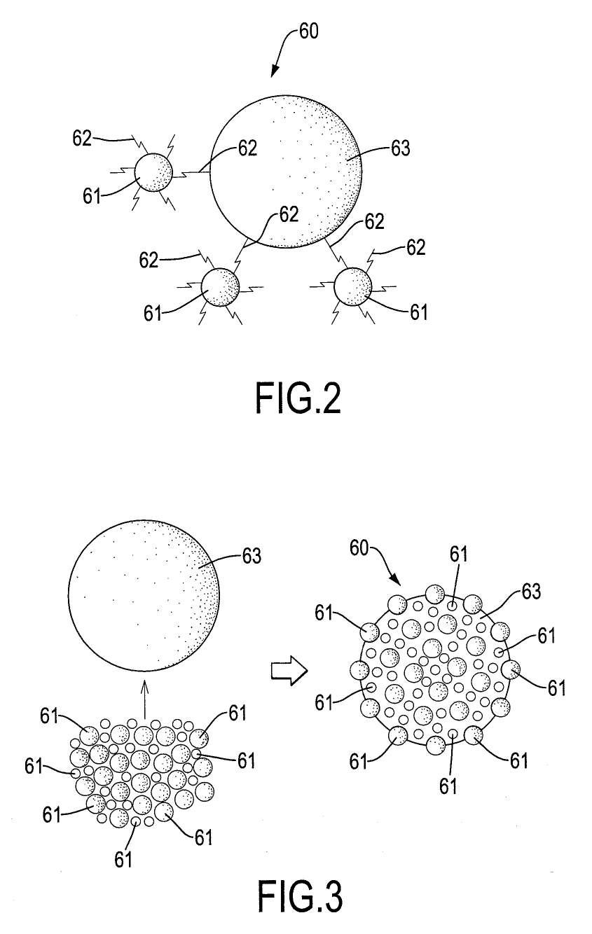

With further reference to FIGS. 2 and 3, the composite nanoparticles (61) can be grafted uniformly on the PMMA microspheres (63) by different volatilization rates of the organic solvent and photonic crystals (60) with a periodic refractive index variation structure being formed. The structure of photonic crystals (60) is similar to an insect's compound eye. Accordingly, a mixture of condensation silicone (71) and photonic crystals (60) is formed.

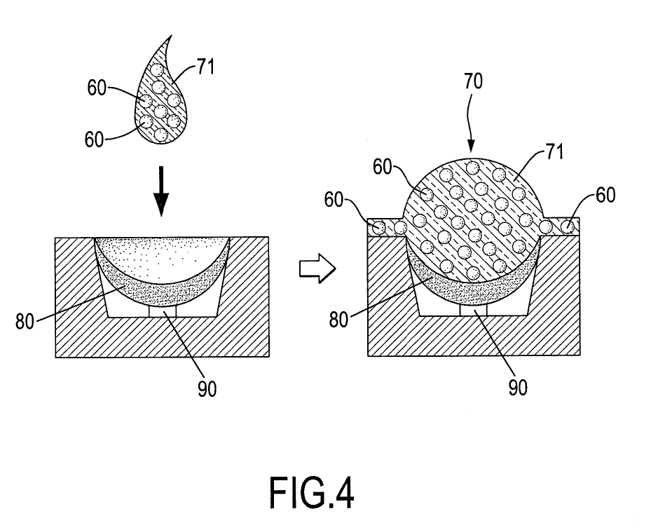

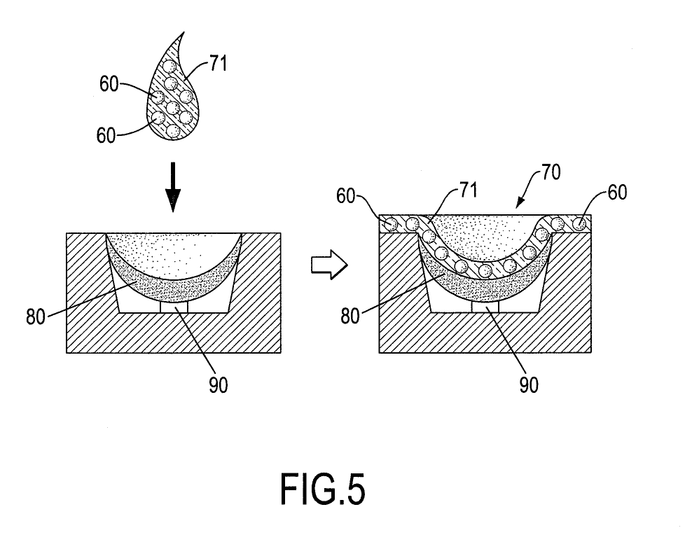

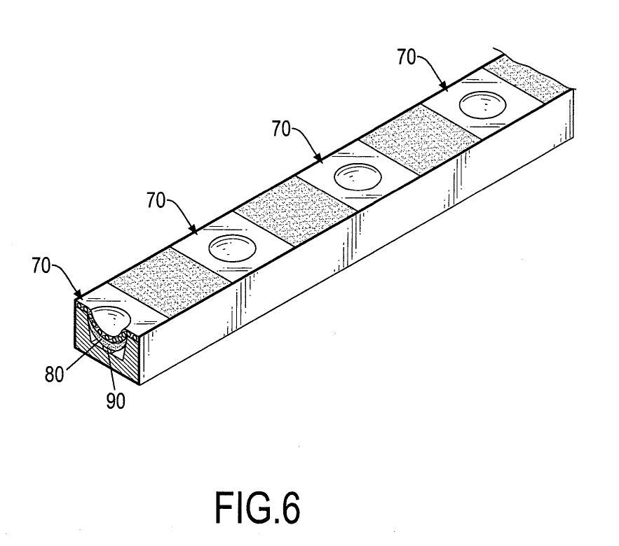

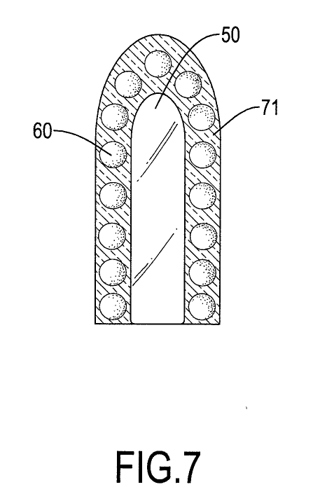

With further reference to FIGS. 4 and 5, the injecting the condensation silicone (71) and photonic crystals (60) onto an LED step (30) injects the mixture of condensation silicone (71) and photonic crystals (60) and an optional curing agent onto an LED fluorescence layer (80) and chip (90) to form an encapsulating layer and a convex or concave microlens (70) on the LED. The curing agent can be added to facilitate curing of the mixture. The convex microlens (70) is spherical and is formed by surface tension of the condensation silicone (71). With further reference to FIG. 6, the mixture of condensation silicone (71) and photonic crystals (60) can also be injected on LED chips arranged in a line to form a series of concave microlenses. With further reference to FIG. 7, the mixture of condensation silicone (71) and photonic crystals (60) can also be injected on an LED product (50) to improve the quality of light emitted.

The method as described has the following advantages. The photonic crystal (60) structure is an integral part of the encapsulating layer of the LED, changes light absorption and scattering of the LED and forms a steric light source. The light emitting range of LEDs is increased and the light dissipation of the LED is eliminated, which enhances the luminous efficiency of LED. Accordingly, a strongly refractive microlens for an LED with condensation silicone is formed and the brightness, homogeneousness, clearness and contrast of light emitted from the LED are improved. Furthermore, the LED manufacturing cost can be reduced by the use of condensation silicone (71).

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A method for manufacturing a strongly refractive microlens for a light emitting diode (LED) with condensation silicone comprising:
forming a mixture of composite nanoparticles and PMMA microspheres by
mixing composite nanoparticles with organic metal coupling agent that encapsulates the composite nanoparticles to form a paste;
dipping the paste into and mixing with a mixed liquid of PMMA microspheres and organic solvent to form a mixture of the composite nanoparticles and the PMMA microspheres;
forming a mixture of condensation silicone and photonic crystals by
adding the mixture of composite nanoparticles and PMMA microspheres to condensation silicone and mixing; and
removing the organic solvent and water from the mixture; and
grafting the composite nanoparticles onto the PMMA microspheres to form photonic crystals; and
injecting the condensation silicone and photonic crystals onto an LED to forming a strongly refractive microlens.

2. The method as claimed in claim 1, wherein
the composite nanoparticles have a diameter in a range of 5 nm-1000 nm and are a mixture of titanium dioxide nanoparticles and silica nanoparticles.

3. The method as claimed in claim 1, wherein the organic solvent is a mixture of the ethanol and methylbenzene.

4. The method as claimed in claim 1, wherein mixing the composite nanoparticles and the PMMA microspheres mixture with the condensation silicone is performed at about 120° C. and near a vacuum to remove the organic solvent and water.

5. The method as claimed in claim 1, wherein the mixture of condensation silicone and photonic crystals further has a curing agent.

6. The method as claimed in claim 2, wherein the weight ratio of titanium dioxide nanoparticles to silica nanoparticles is 4 to 1.

7. The method as claimed in claim 6, wherein the organic metal coupling agent is selected from the group consisting of titanate, aluminate and stannate coupling agent.

8. The method as claimed in claim 7, wherein the PMMA microspheres have a diameter in a range of 0.1 μm-20 μm.

9. The method as claimed in claim 8, wherein the PMMA microspheres have a weight ratio to the composite nanoparticles of 80:20 through 99:1.
